(19) United States
(12) Patent Application Publication
(10) Pub. No.: US 2006/0034116 A1
(43) Pub. Date: Feb. 16, 2006

(54) Cross point array cell with series connected semiconductor diode and phase change storage media

(76) Inventors: Chung H. Lam, Peekskill, NY (US); Hon-Sum P. Wong, Palo Alto, CA (US)

Correspondence Address: Law Office of Charles W. Peterson, Jr., Suite 100, 11703 Bowman Green Dr., Reston, VA, 20190, US

(21) Appl. No.: 10/918,101

(22) Filed: Aug. 13, 2004

(51) Int. Cl. G11C 11/00

(52) U.S. Cl. 365/151

(57) ABSTRACT

A storage cell that may be a memory cell, and an integrated circuit (IC) chip including an array of the memory cells and a method of forming the IC. Each storage cell includes a series connected diode and storage media formed between a top an bottom electrode. The diode is a vertical diode and may be formed in a semiconductor nanowire.

### CROSS REFERENCE TO RELATED APPLICATION

The present invention is related to U.S. application Ser. No. 10/732,582 entitled “FIELD EMISSION PHASE CHANGE DIODE MEMORY” to Stephen S. Furkay et al. and to U.S. application Ser. No. 10/732,580 entitled “PHASE CHANGE TIP STORAGE CELL” to David V. Horak et al., both filed Dec. 10, 2003 and assigned to the assignee of the present invention.

### BACKGROUND OF THE INVENTION

1. Field of the Invention

The present invention is related to nonvolatile solid state storage and particularly to an integrated circuit (IC) chip with an array of non volatile solid state storage cells with a phase change material memory element.

2. Background Description

Solid state phase change materials that are chalcogen (Group VI elements such as sulfur (S), selenium (Se) and tellurium (Te)) alloys with at least one of germanium (Ge), arsenic (As), silicon (Si), and antimony (Sb)) are known as chalcogenides and are well known. Chalcogenides exist in at least two different classifiable solid states or phases. The most extreme two states can be classified simply as amorphous and crystalline states with other less easily discernable states ranging between those two extreme states. The amorphous state has a disordered atomic structure and the crystalline state generally is polycrystalline. Each phase has very different electrical properties. In its amorphous state, the material behaves as an insulator below some turn on threshold voltage (Vₜ), i.e., acts as an open circuit; in its crystalline state, the same material behaves resistively. The resistivity of these materials varies in between amorphous and crystalline states by as much as 6 orders of magnitude.

In particular, when heat is applied to some phase change chalcogenides, the material switches phases from one (e.g., amorphous phase) state to a second (e.g., crystalline phase) state. FIG. 1 shows an example of a current verses voltage (I-V) characteristic for a typical chalcogenide material that is essentially resistive in its crystalline phase and a nonlinear or stepped resistance in its amorphous phase with substantially reduced current below Vₜ. So, crystalline phase change material conducts current resistively and amorphous phase change material, more or less, acts as a diode. The transitions between these states is selectively reversible with heat, i.e., the phase change material may be set/reset. As with anything that has two or more discernable and selectable states, one of the 2 stable states can be designated as a logic one and the other a logic zero. Thus, phase change material has found use in storage devices and particularly, for non-volatile storage, e.g., as a memory cell storage media. In addition, multiple bit memory elements have been made using the intermediate states inherent in the variation in resistivity between amorphous and crystalline.

In particular, phase change memory cells have been used in array normally referred to as a cross point memory array. Analogous to well known magnetic core memory, a typical cross point memory array includes bit lines and word lines on two orthogonal wiring planes. Cell selection is the intersection of a word line with a bit line. Each cell may be accessed, e.g., by pulling a word line high, holding a bit line low and checking whether the current flow between the two indicates the presence of a resistor or a diode in the cell. However, regardless of whether the phase change material in a cell is amorphous or crystalline and even when the voltage across the cell is below the amorphous turn on threshold, each cell conducts some current. Half selected cells (e.g., cells on a selected word line but unselected bit lines or a selected bit line but unselected word lines), in particular, conduct significant current that may be considered leakage current. For a typical integrated circuit (IC) chip, this unselected leakage is exacerbated by the size of the particular array and, correspondingly, the number of leaking cells. Accordingly, reducing this half select leakage would considerably reduce phase change memory power consumption.

Thus, there is a need to reduce or eliminate leakage and, especially, half select leakage in phase change memory cells.

### SUMMARY OF THE INVENTION

It is a purpose of the invention to reduce leakage phase change material in memory cells;

It is another purpose of the invention to eliminate half select cell leakage phase change material in memory cells.

The present invention relates to a storage cell that may be a memory cell, and an integrated circuit (IC) chip including an array of the memory cells and a method of forming the IC. Each storage cell includes a series connected diode and storage media formed between a top an bottom electrode. The diode is a vertical diode and may be formed in a semiconductor nanowire.

### BRIEF DESCRIPTION OF THE DRAWINGS

The foregoing and other objects, aspects and advantages will be better understood from the following detailed description of a preferred embodiment of the invention with reference to the drawings, in which:

FIG. 1 shows an example of a current verses voltage (I-V) characteristic for a typical phase change memory cells;

FIG. 2 shows an example of a preferred embodiment low leakage nonvolatile storage device according to the present invention;

FIG. 3A shows an example of a flow diagram of steps for forming preferred embodiment low leakage nonvolatile storage devices;

FIG. 3B shows an example of a flow diagram of forming preferred embodiment diodes in low leakage nonvolatile cross point storage array cells;

FIG. 4A shows an example of a three dimensional (3D) exposed view of a cross point storage array of preferred embodiment low leakage nonvolatile cells;

FIG. 4B is a cross section of a semiconductor chip including the preferred embodiment cross point storage array of FIG. 4A through B-B and in more detail;

FIG. 5 shows an example of typical chalcogenide memory programming temperature evolution profiles for preferred embodiment cross point cells.

### DESCRIPTION OF PREFERRED EMBODIMENTS

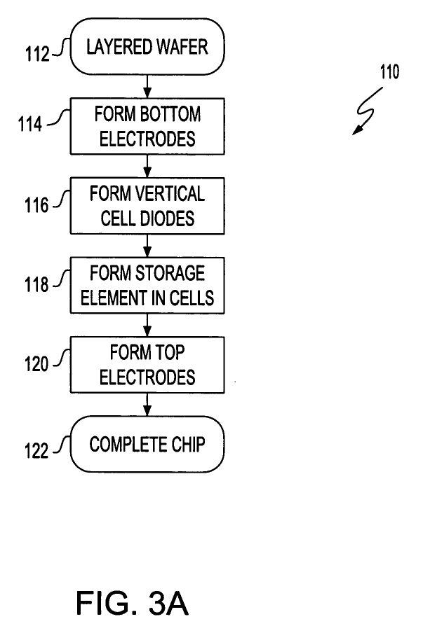

Turning now to the drawings and more particularly FIG. 2 shows an example of a preferred embodiment low leakage nonvolatile storage device 100 according to the present invention, e.g., a nonvolatile cell in a cross point storage array of low leakage cells. In particular, each preferred embodiment low leakage storage cell 100 includes a semiconductor diode 102, preferably a vertical diode in a semiconductor nanowire, in series with storage media 104, e.g., chalcogenide phase change material. Each low leakage cell 100 has at least two states; preferably, a resistive state wherein the vertical diode 102 is in series with resistive crystalline phase change storage media 104; and, a stepped state with the stepped resistance of the amorphous phase change storage media 104 in series with the vertical diode 102. For examples of phase material cells in a cross point array and switching phases to switch between electrical states, see e.g., U.S. application Ser. No. 10/732,582 entitled “FIELD EMISSION PHASE CHANGE DIODE MEMORY” to Stephen S. Furkay et al. and to U.S. application Ser. No. 10/732,580 entitled “PHASE CHANGE TIP STORAGE CELL” to David V. Horak et al., both filed Dec. 10, 2003, assigned to the assignee of the present invention and incorporated herein by reference. Although the storage media 104 for preferred embodiment storage cells 100 is described with reference to phase change material memory elements, this is for example only and not intended as a limitation. Any other suitable storage media or device may be substituted, including for example, polymers, perovskites, magnetic tunnel junction, organic molecules or equivalents thereof.

Cell behavior may be understood using superposition in that the cell voltage (V_{cell}) is the sum of the diode voltage (V_{d}) and the storage media voltage (Vₛₘ), i.e., (V_{cell}=V_{d}+Vₛₘ). Whenever the voltage across any low leakage cell 100 (V_{cell}) is below the turn on voltage (Vₒₙ) of the vertical diode 102 (i.e., V_{cell}<Vₒₙ), the cells 100 behave substantially identically, i.e., as an open circuit. Similarly, with the cell voltage above the sum of the diode voltage and the phase change material (i.e., V_{cell}>Vₒₙ+Vₜ), the cells 100 behave substantially identically, i.e., as a phase change material resistor. Between these two limits (i.e., Vₒₙ<V_{cell}<Vₒₙ+Vₜ), however, cell behavior depends upon the state of the phase change material storage media 104. Thus, in this range cells 100 with amorphous phase change material storage media 104 continue to behave as an open circuit; while, cells 100 with crystalline phase change material storage media 104 continue to behave as a phase change material resistor. Accordingly, for purposes of discussion of the present invention, low leakage cells 100 with amorphous phase change material storage media 104 are referred to herein as being in the cell's off state; low leakage cells 100 with crystalline phase change material storage media 104 are referred to herein as being in the cell's on state.

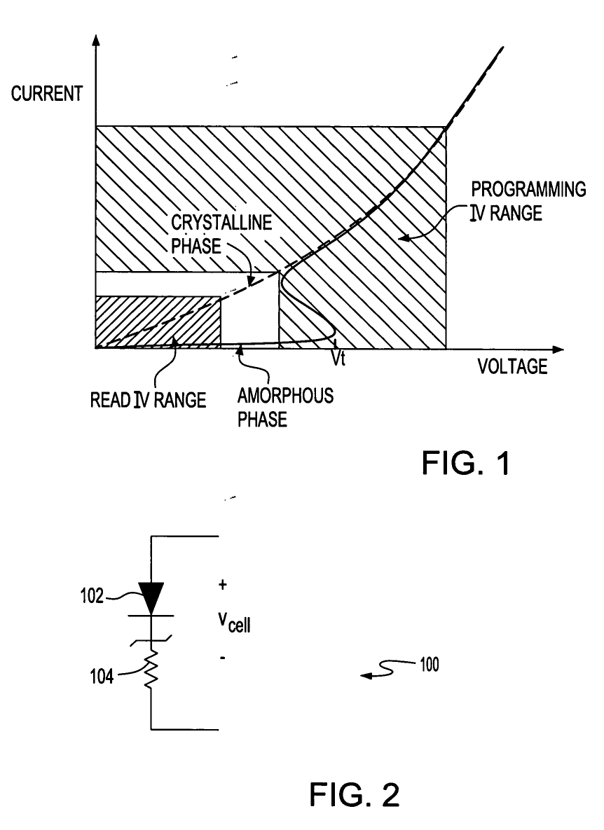

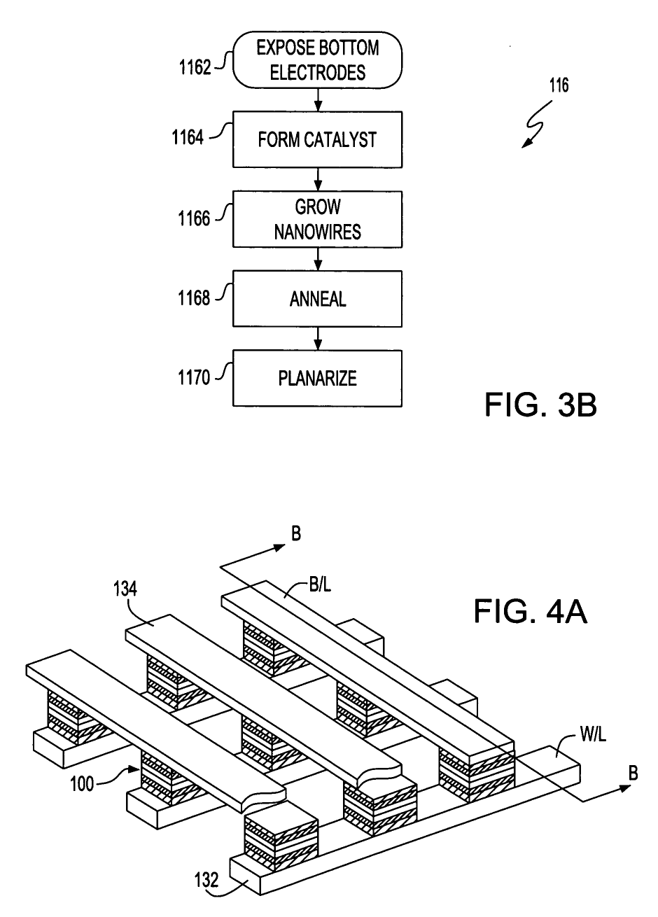

FIG. 3A shows an example of the steps 110 of forming preferred embodiment low leakage nonvolatile storage devices according to the present invention, e.g., in a cross point storage array of low leakage memory cells such as storage device 100 of FIG. 1. Cell formation begins in step 112 with a layered wafer. In particular, the layered wafer may be a partially patterned integrated circuit with standard insulated gate field effect transistor (FET) technology devices in the complementary FET technology, commonly referred to as CMOS. Memory cells 100 are formed as described hereinbelow between 2 conductor layers, that are referred to as top and bottom electrode layers. Further, circuit devices, both N-type FETs (NFETs) and P-type FETs (PFETs), may be connected together by wiring that may be, in part, on one or both of the 2 conductor layers. So, in step 114 bottom electrodes are formed in a conductor layer at the surface of the layered wafer (e.g., a silicon on insulator (SOI) wafer) and an insulating layer is grown over the bottom electrode layer. Then in step 116, vertical diodes (e.g., 102 in FIG. 2) are each formed on a bottom electrode at each cell location.

Thus having formed the vertical diode PN junctions at each cell, in step 118 the phase change material storage media (e.g., 104) is formed on the vertical diodes in each of the cell locations. It should be noted that although described herein as phase change material storage media, this is for example only. Any other suitable storage material may be substituted without departing from the spirit or scope of the invention. Suitable such other materials include, for example, polymers, perovskites, magnetic tunnel junction material and programmable organic molecules. The array is completed in step 120 by forming top electrodes over the cells. By orienting the bottom electrodes in one direction and the top electrodes in a second direction, each cell is uniquely identifiable by the intersection of one bottom electrode with one top electrode. Finally in step 122, using standard semiconductor manufacturing back end of the line (BEOL) steps, the memory (macro, chip, etc.) is completed.

FIG. 3B shows an example of the step 116 of forming preferred embodiment diodes in low leakage nonvolatile cross point storage array cells according to the present invention. The diodes (102 in FIG. 1) may be in nanowires that are grown without a semiconductor seed and in situ or ex situ doped to form a diode junction in each nanowire. So in this example, first in step 1162 the bottom electrodes are exposed in the cell areas, e.g., cutting trenches oriented orthogonally to the underlying bottom electrode. In step 1164 a metal nanoparticle (e.g., Au) catalyst layer is formed for nanowire growth on the exposed bottom electrodes. Catalysts for nanowire growth can be formed at these cross-point locations using any suitable approach, e.g., selective deposition or lift off. A catalyst may be deposited using electroplating. Alternately, a sacrificial layer may be deposited for lift off, e.g., a self assembled monolayer (SAM) material. The sacrificial layer selectively adheres to the insulating dielectric, while the exposed bottom electrode metal remains exposed. Next, a layer of the nanowire catalyst is deposited on the wafer. When the SAM is removed from the insulating dielectric, the deposited catalyst only remains on the previously exposed bottom electrode metal at the cross-points. The metal nanoparticle catalyst encourages semiconductor growth only on and extending upward from the exposed portions of bottom electrodes. So in step 1166, using vapor liquid solid (VLS) growth, vertical semiconductor nanowires (e.g., crystalline germanium (Ge) or silicon (Si) nanowires) are formed at relatively low temperatures (<400° C. and more particularly at 275° C.) to avoid destroying or damaging underlying electrical components, e.g., CMOS circuits. Further, the temperature is low enough that the nanowire formation is compatible with conventional interconnect metallization processing temperatures. Thereafter, in step 1168 the wafer is thermally annealed for dopant activation. Finally, in step 1170 a suitable insulating material may be deposited, e.g., nitride, to fill the trenches and the wafer is planarized coplanar with and exposing the upper end of the diodes 102.

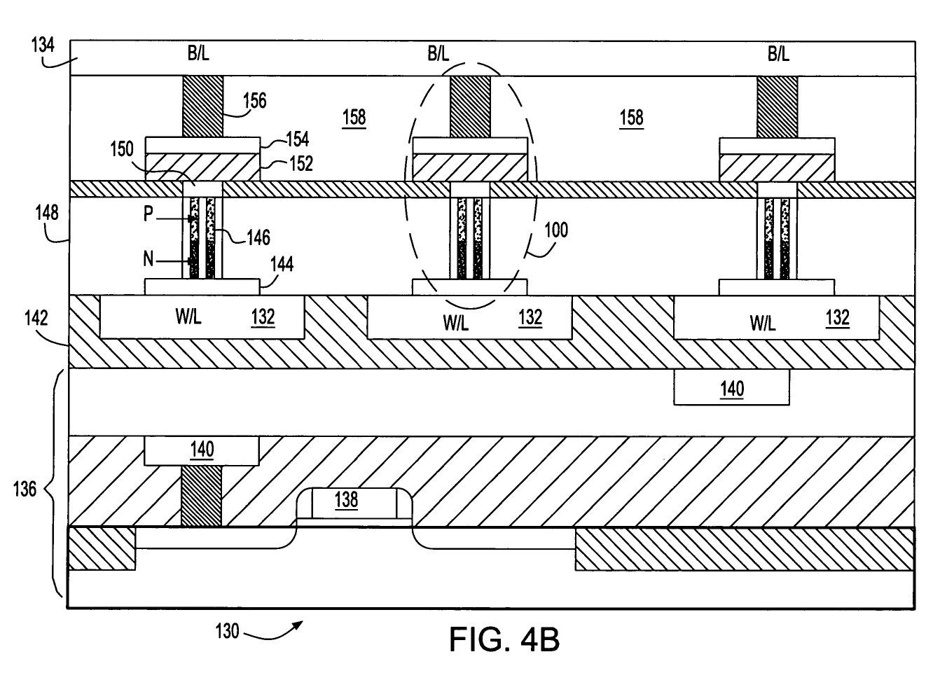

FIG. 4A shows an exposed three dimensional (3D) view of an example of a preferred embodiment cross point storage array 130 of low leakage nonvolatile storage device 100 cells according to the present invention. FIG. 4B is a cross section of the preferred embodiment cross point storage array 130 of FIG. 4A through B-B in more detail. Bottom electrode word lines 132 are oriented in one direction and top electrode bit lines 134 are oriented in a second, orthogonal direction. Each cell is located at the intersection of each word line 132 with each bit line 134 and each bit line 134 with each word line 132.

As can be further seen from FIG. 4B, the array 130 is formed on a typical integrated circuit in a layered wafer 136, e.g., with FETs 138 connected together by wires 140 on a number of wiring layers above the FETs 138. The word lines 132 in the bottom electrode layer are formed in or through an insulation layer 142 on the layered wafer 136. A thin metal nanoparticle catalyst layer 144, preferably less than 10 nm thick, remains on each word line 132 in each cell 100 at the bottom of each trench. A nanowire 146, preferably 30-50 nm long, extends upward in a diode layer 148 from the metal nanoparticle catalyst layer 144 at the word line 132. In this example, the lower portion of the nanowire 146 is doped with N-type dopant and the upper portion is doped with P-type dopant forming a vertical diode, e.g., 102 in FIG. 1. The trenches are formed through an interlayer dielectric material, preferably silicon oxide (SiO₂) or silicon nitride (SiN), in the diode layer 148 that isolates adjacent vertical nanowire 146 diodes from each other in one direction that, preferably, are separated by a vacuum in the otherdirection. A heater 150, preferably a 50 nm thick layer of titanium nitride (TiN) or tantalum nitride (TaN), is formed on each nanowire 146 for programming the storage media 152, thereabove and that, further, serves as a barrier between the nanowire 146 and the storage media 152. The storage media 152 is preferably 10-50 nm thick and capped with resistive material 154, preferably a 50 nm thick layer of TiN or TaN, that serves as a barrier and forms a suitable resistive contact between the storage media 152 and a top electrode connection via 156. Preferably, the top electrode connection via 156 is tungsten or copper. Dielectric fill material 158, preferably SiO₂, isolates adjacent top electrode vias 156. Finally, bit line 134 in the top electrode layer contacts each electrode connection via 156.

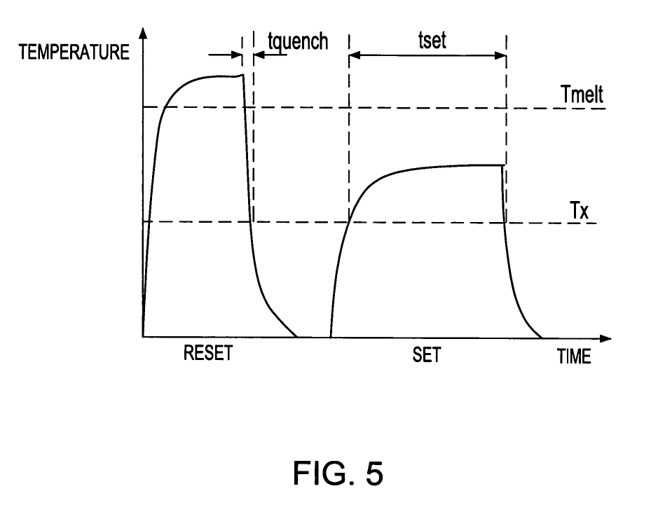

FIG. 5 shows an example of typical chalcogenide memory programming temperature evolution profiles for preferred embodiment cross point cells. Switching states is effected by heating the cell storage media 152 to switch phases: switching to its amorphous (RESET) phase by heating the storage media 152 to Tₘₑₗₜ and allowing it sufficient time to cool (t_{quench}); and, alternately, crystallizing (SET) the storage media 152 by heating it to Tₓ and allowing it sufficient time to cool (tₛₑₜ). Thus, by switching the storage media 152 between crystalline and amorphous phase and back, the cell switches from having a diode in series with resistor and in series with a stepped resistor. So, for example, amorphous storage media 152 may be a logic zero and crystalline storage media 152 may be a logic one.

Advantageously, preferred embodiment cells, e.g., 100 in FIG. 1, include nanowire diodes 102 formed at temperatures low enough to be compatible with conventional interconnect metallization processing temperatures. These nanowire diodes 102 allow memory cell scaling to sub-50 nm and beyond. Further, preferred embodiment nanowires 102 are a single crystal to assure maximum carrier mobility. So, the current transport mechanism in the nanowire diodes 102 is governed by a ballistic transport mechanism that is practically size independent. Thus, the nanowire diodes 102 exhibit an improved current density that is required for programming memory elements 104. In addition, the leakage in such low leakage cells 100 is dramatically reduced both for unselected and half selected cells. For example, in a 1.2 volt technology and with V_{d}=0.7 volts (0.7V) and Vₜ=0.5V, although off cells may eventually exceed that upper limit and behave resistively, such behavior occurs only toward the end of the particular access. Furthermore, the voltage across half selected cells may never reach Vₒₙ and so, half select leakage may effectively eliminated for not only unselected and half selected off cells, but also for half selected on cells as well.

While the invention has been described in terms of preferred embodiments, those skilled in the art will recognize that the invention can be practiced with modification within the spirit and scope of the appended claims.

What is claimed is:

1. A storage device comprising:
a first electrode;
a nanowire diode having one conductive terminal connected to said first electrode;
a storage media layer disposed on said diode and connected to said diode at a second conductive terminal; and
a second electrode connected to said storage media.

2. A storage device as in claim 1, wherein said nanowire diode is a vertical diode extending upward from said first electrode and said storage media is disposed on a top end of said vertical diode.

3. A storage device as in claim 2, wherein said vertical diode is in a semiconductor nanowire.

4. A storage device as in claim 3, wherein said semiconductor nanowire is disposed on a metal nanoparticle catalyst layer, said metal nanoparticle catalyst layer connecting said one conductive terminal to said first electrode.

5. A storage device as in claim 3, wherein said storage media layer is a phase change material layer.

6. A storage device as in claim 5, wherein said phase change material layer is a chalcogenide layer.

7. A storage device as in claim 3, wherein said semiconductor nanowire is a silicon nanowire.

8. A storage device as in claim 3, wherein said semiconductor nanowire is a germanium nanowire.

9. An integrated circuit (IC) including a memory array, each of said memory array comprising:
a first wiring layer of a plurality of wires oriented in a first direction;
a second wiring layer of a plurality of wires oriented in a second direction; and
an array of memory cells disposed between said first wiring layer and said second wiring layer, each of said memory cells comprising:
a vertical nanowire diode on and connected to a first electrode said first electrode being one of said plurality of wires in said first wiring layer, and
a phase change layer disposed on and connected to said vertical diode, and a second electrode contacting said phase change layer, said second electrode being one of said plurality of wires in said second wiring layer.

10. An IC as in claim 9, wherein each said vertical nanowire diode is in a semiconductor nanowire and said storage media layer is a phase change material layer.

11. An IC as in claim 10, wherein each said semiconductor nanowire is disposed on a metal nanoparticle catalyst layer, said metal nanoparticle catalyst layer connecting said one conductive terminal to said first electrode.

12. An IC as in claim 9, wherein said phase change material layer is a chalcogenide layer.

13. A IC as in claim 12, wherein said semiconductor nanowire is a germanium nanowire.

14. A IC as in claim 12, wherein said semiconductor nanowire is a silicon nanowire.

15. A method of forming an integrated circuit (IC) including a memory array, said method comprising the steps of:
a) forming a bottom electrode layer;
b) forming a nanowire diode in each memory cell location, each said diode being connected to a word line in said bottom electrode array;
c) forming a storage media layer on said each diode; and
d) forming a top electrode layer, said storage media layer in said each memory cell location contacting a bit line in said top electrode layer.

16. A method of forming an IC as in claim 15, wherein said bottom layer is formed on a CMOS silicon on insulator (SOI) integrated circuit (IC) chip layer.

17. A method of forming an IC as in claim 16, wherein the step (b) of forming nanowire diodes in each said memory cell location comprises the steps of:
i) selectively exposing portions of each said word line in said each memory cell location;
ii) forming a nanoparticle catalyst layer on exposed said portons; and
iii) growing nanowires on potions of said nanoparticle catalyst layer on said exposed portions, diodes being formed in said nanowires.

18. A method of forming an IC as in claim 17, wherein the step (i) of selectively exposing portions of the bottom electrode comprises forming trenches though a surface layer, said trenches being formed orthogonal to said first electrodes in said first electrode layer.

19. A method of forming an IC as in claim 18, wherein the step (iii) of growing nanowires comprises a vapor solid growth with in situ doping, and said method further comprises the step of:
iv) annealing said IC, dopant in said nanowires being activated by said anneal.

20. A method of forming an IC as in claim 19, wherein the step (c) of forming said storage media layer comprises forming a heater on an upper end of said diode nanowire and forming said storage media layer on said heater.
